(19) United States
(12) Patent Application Publication
(10) Pub. No.: US 2026/0107784 A1
(43) Pub. Date: Apr. 16, 2026

(54) ELECTRONIC COMPONENT INTEGRATION METHOD USING POLYMER STAMP, ELECTRONIC COMPONENT INTEGRATION DEVICE, INTERPOSER MANUFACTURING METHOD AND INTERPOSER

(71) Applicant: POSTECH RESEARCH AND BUSINESS DEVELOPMENT FOUNDATION, Pohang-si (KR)

(72) Inventors: Seok KIM, Pohang-si (KR); U Hyeon KIM, Pohang-si (KR); Ho Hyun KEUM, Pohang-si (KR)

(73) Assignee: POSTECH RESEARCH AND BUSINESS DEVELOPMENT FOUNDATION, Pohang-si (KR)

(21) Appl. No.: 19/352,244

(22) Filed: Oct. 7, 2025

(30) Foreign Application Priority Data
Oct. 10, 2024 (KR) 10-2024-0137815

(51) Int. Cl. H01L 21/48; H01L 23/00; H01L 23/498

(52) U.S. Cl. CPC H10W 70/05; H10W 90/701; H10W 72/072; H10W 72/07232; H10W 72/241

(57) ABSTRACT

A method for integrating electronic components using a polymer stamp is provided. The method includes picking up a first electronic component with a first conductive metal exposed at its lower portion using the polymer stamp, positioning the first electronic component on a substrate having at least partially exposed metal wiring using the polymer stamp, pressing and heating the first conductive metal and the metal wiring so that low-temperature bonding occurs between them, and separating the first electronic component from the polymer stamp.

### CROSS REFERENCE TO RELATED APPLICATION

This application claims the benefit of Korean Patent Application No. 10-2024-0137815, filed on Oct. 10, 2024, the contents of which are all hereby incorporated by reference herein in their entirety.

### BACKGROUND OF THE INVENTION

### Field of the Invention

The present invention relates to an electronic component integration method using a polymer stamp and an electronic component integration device, and more particularly, to a method and a device for integrating semiconductor components through low-temperature bonding using a polymer stamp.

The present invention also relates to an interposer and an interposer manufacturing method, and more particularly, to an interposer capable of being laminated with heterogeneous or homogeneous metals and a method of manufacturing the same.

### Related Art

An interposer is an intermediate element that connects a semiconductor chip to a substrate or connects semiconductor chips to each other, and is an essential component in the transition of semiconductor packaging from two-dimensional device miniaturization to three-dimensional device stacking.

High Bandwidth Memory (HBM) is a memory in which DRAM cells are stacked in a 2.5-dimensional (2.5D) or three-dimensional (3D) structure, and recently, integration technology enabling stacking of twelve DRAM layers within 775 microns has been commercialized.

In this case, the thickness of each DRAM is known to be approximately 30 μm, and a carrier wafer is employed in the process of fabricating such extremely thin devices. A device wafer is temporarily bonded to the carrier wafer using a temporary bonding layer, and then unnecessary portions of the backside of the device wafer are processed to thin the device wafer. Subsequently, the temporary bonding layer is removed by heat or a chemical solution to separate the thin device.

However, during such processes, continuous damage may occur to the device during wafer grinding, and warpage is likely to occur in the process of debonding the thin device.

### SUMMARY OF THE INVENTION

The present invention aims to provide an electronic component integration method and an electronic component integration device capable of high-speed integration.

The present invention also aims to provide an electronic component integration method and an electronic component integration device capable of low-temperature bonding using heterogeneous or homogeneous metals.

In addition, the present invention aims to provide an interposer capable of low-temperature bonding using heterogeneous or homogeneous metals and a method of manufacturing the same.

The problems addressed by the present invention are not limited to those described above, and other problems not explicitly mentioned can be clearly understood by those skilled in the art from the following description.

An electronic component integration method according to an embodiment of the present invention for solving the above-described problems includes: picking up a first electronic component having a first conductive metal exposed at a lower portion using a polymer stamp; positioning the first electronic component on a substrate having at least a portion of a metal wiring exposed on a surface using the polymer stamp; pressing and heating the first conductive metal and the metal wiring using the polymer stamp such that low-temperature bonding is performed between the first conductive metal and the metal wiring; and separating the first electronic component from the polymer stamp.

In one embodiment, in the step of pressing and heating the first conductive metal and the metal wiring, the heating temperature may be lower than the melting points of the first conductive metal and the metal wiring.

In one embodiment, the first electronic component may include a second conductive metal electrically connected to the first conductive metal and exposed at an upper portion, and the method may further include: picking up a second electronic component having a first conductive metal exposed at a lower portion using the polymer stamp; positioning the second electronic component on the first electronic component using the polymer stamp; pressing and heating the second conductive metal of the first electronic component and the first conductive metal of the second electronic component using the polymer stamp such that low-temperature bonding is performed between the second conductive metal of the first electronic component and the first conductive metal of the second electronic component; and separating the second electronic component from the polymer stamp.

In one embodiment, in the step of pressing and heating the second conductive metal of the first electronic component and the first conductive metal of the second electronic component, the heating temperature may be lower than the melting points of the second conductive metal of the first electronic component and the first conductive metal of the second electronic component.

In one embodiment, the polymer stamp may include a Shape Memory Polymer (SMP).

In one embodiment, prior to the step of picking up the first electronic component using the polymer stamp, the method may further include: heating the polymer stamp to a temperature equal to or higher than the glass transition temperature; pressing the heated polymer stamp onto the first electronic component to increase a contact area between the polymer stamp and the first electronic component; and cooling the polymer stamp.

In one embodiment, in the step of pressing and heating the first conductive metal and the metal wiring, the heating temperature may be equal to or higher than the glass transition temperature.

In one embodiment, the polymer stamp may include PDMS (polydimethylsiloxane).

In one embodiment, the first conductive metal may include copper.

In one embodiment, the second conductive metal may include tin.

In one embodiment, the first electronic component may include an interposer comprising a device layer through which the first conductive metal passes vertically, a lower bump formed by the first conductive metal exposed at the lower portion of the device layer, an upper bump formed by the first conductive metal exposed at the upper portion of the device layer, and a second conductive metal formed on the upper surface of the upper bump.

In one embodiment, the second electronic component may include an interposer comprising a device layer through which the first conductive metal passes vertically, a lower bump formed by the first conductive metal exposed at the lower portion of the device layer, an upper bump formed by the first conductive metal exposed at the upper portion of the device layer, and a second conductive metal formed on the upper surface of the upper bump.

An interposer manufacturing method according to an embodiment of the present invention for solving the above-described problems includes: preparing a substrate to be processed, which includes a handling layer, an intermediate layer stacked on the handling layer, and a device layer stacked on the intermediate layer; forming a via hole in the device layer; etching a portion of the intermediate layer to form a bump space below the via hole; forming a lower bump in the bump space using a first conductive metal and forming a first conductive metal layer on the upper surface of the device layer connected to the lower bump; removing the intermediate layer to separate the device layer from the handling layer; and forming a second conductive metal layer on the upper surface of the first conductive metal layer.

In one embodiment, the first conductive metal layer may include a wiring pattern formed on the upper surface of the device layer, a via portion filled in the via hole, and an upper bump extending upward from the via portion, and the second conductive metal layer may be formed on the upper bump.

In one embodiment, the upper bump may protrude above the wiring pattern.

In one embodiment, low-temperature bonding by eutectic fusion or diffusion may be performed between the first conductive metal and the second conductive metal at a temperature lower than the melting points of the first conductive metal and the second conductive metal.

In one embodiment, the first conductive metal may include copper.

In one embodiment, the second conductive metal may include tin.

An interposer according to an embodiment of the present invention for solving the above-described problems may include: a device layer having at least one via hole passing vertically, a via portion filled in the via hole, an upper bump connected to the via portion and exposed at the upper portion of the device layer, a lower bump connected to the via portion and exposed at the lower portion of the device layer, formed by a first conductive metal layer, and a second conductive metal layer formed of the second conductive metal on the upper surface of the upper bump.

In one embodiment, low-temperature bonding by eutectic fusion or diffusion may be performed between the first conductive metal and the second conductive metal at a temperature lower than the melting points of the first conductive metal and the second conductive metal.
Other details of the disclosure are included in the detailed description and the accompanying drawings.

According to the embodiments of the disclosure, the effects are at least as follows.

Electronic components including the interposer can undergo low-temperature bonding through eutectic fusion, diffusion, or similar processes, thereby significantly reducing the time required for the integration process and minimizing adverse thermal effects.

Since grinding and debonding processes of the carrier wafer are not required, issues such as damage or warpage of thin-film devices caused by these processes can be avoided.

By transferring and aligning the electronic components using a dry-adhesion polymer stamp (SMP, PDMS) and performing bonding in a low-temperature and low-pressure environment, energy and resources required for the process can be saved, and high-speed and high-precision integration can be achieved.

Because the bonding between the substrate and the electronic components or between electronic components themselves is performed through direct metal-to-metal connection without using separate conductive adhesive materials, higher process efficiency is achieved, and high-precision bonding is possible.

The effects of the disclosure are not limited to those described above, and various other effects are included in the foregoing description.

### BRIEF DESCRIPTION OF THE DRAWINGS

FIG. 1 is a cross-sectional view schematically illustrating an interposer according to an embodiment of the present invention.

FIG. 2 is a flowchart illustrating an interposer manufacturing method according to an embodiment of the present invention.

FIGS. 3A and 3B are views for explaining the interposer manufacturing method according to an embodiment of the present invention.

FIG. 4 is a flowchart illustrating an electronic component integration method according to an embodiment of the present invention.

FIG. 5 is a view for explaining the electronic component integration method according to an embodiment of the present invention.

FIG. 6 is a view for explaining a method of stacking and integrating electronic components using the electronic component integration method according to an embodiment of the present invention.

FIG. 7 is a flowchart illustrating an electronic component integration method according to another embodiment of the present invention.

FIG. 8 is a view for explaining the electronic component integration method according to another embodiment of the present invention.

FIG. 9 is a view for explaining a method of stacking and integrating electronic components using the electronic component integration method according to another embodiment of the present invention.

FIG. 10 is a view schematically illustrating an electronic component integration device according to an embodiment of the present invention.

### DETAILED DESCRIPTION

The advantages and characteristics of the disclosure and a method for achieving the advantages and characteristics will become more apparent from embodiments described below in detail in conjunction with the accompanying drawings. However, the disclosure is not limited to the disclosed embodiments, but may be implemented in various different ways. The embodiments are provided to only complete the disclosure and to allow those skilled in the art to understand the category of the disclosure. The disclosure is defined by the category of the claims.

In addition, embodiments of the disclosure will be described with reference to cross-sectional views and/or schematic views as idealized exemplary illustrations. Therefore, the illustrations may be varied in shape depending on manufacturing techniques, tolerance, and/or etc. Further, elements in the drawings may be relatively enlarged or reduced for convenience of description. Like numerals refer to like elements throughout.

Referring to the drawings for explaining an interposer, an interposer manufacturing method, an electronic component integration method, and an electronic component integration device according to embodiments of the present invention, the present invention will be described in detail.

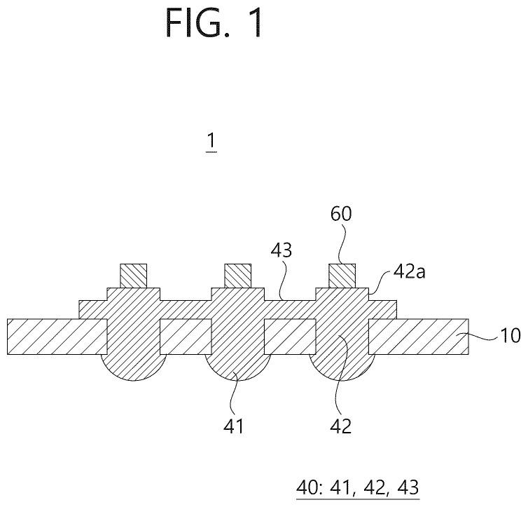

FIG. 1 is a cross-sectional view schematically illustrating an interposer according to an embodiment of the present invention.

Referring to FIG. 1, an interposer 1 according to an embodiment of the present invention includes a device layer 10, a first conductive metal layer 40, and a second conductive metal layer 60.

The interposer 1 according to an embodiment of the present invention may be an ultrathin silicon interposer based on a silicon-on-insulator (SOI) wafer, but the interposer according to the present invention is not limited thereto.

The device layer 10 may be an SOI wafer having a thickness of 3 to 30 μm.

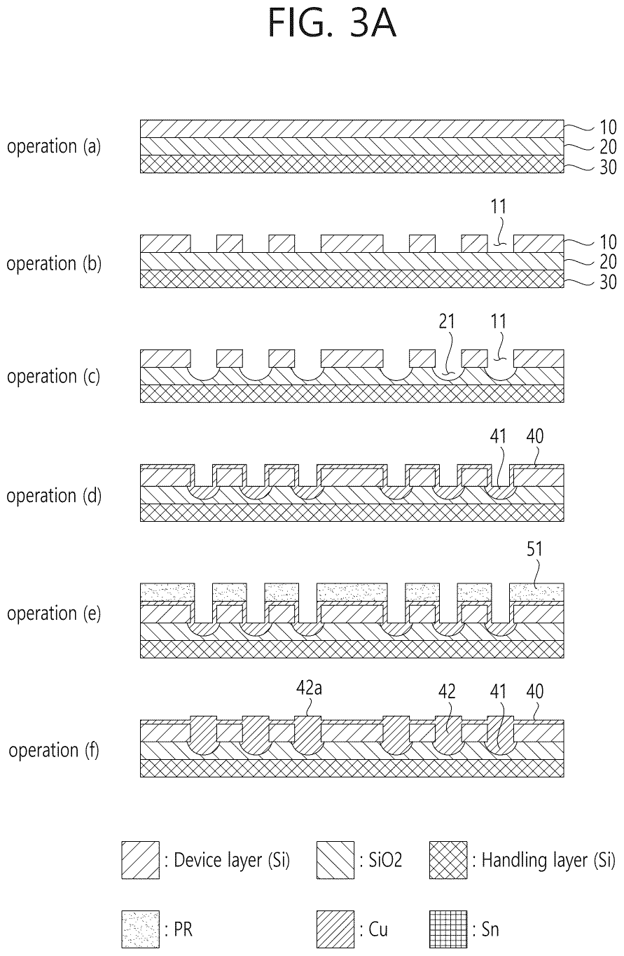

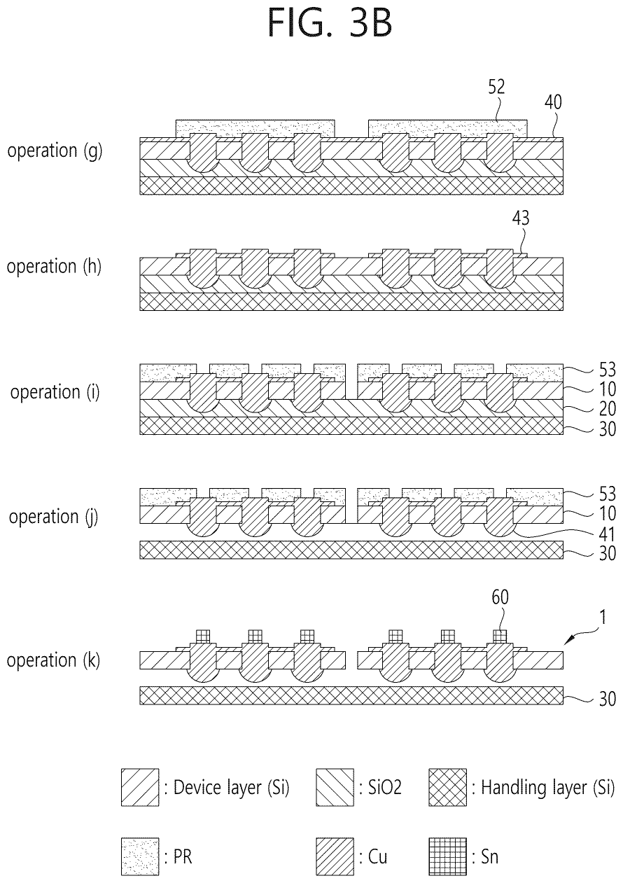

The first conductive metal layer 40 is formed of a first conductive metal and includes a via portion 42 filling a via hole 11 (see FIG. 3A) penetrating the device layer 10 vertically, an upper bump 42a connected to the via portion 42 and exposed on the top of the device layer 10, a lower bump 41 connected to the via portion 42 and exposed on the bottom of the device layer 10, and a wiring pattern 43 formed on the top surface of the device layer 10.

The lower bump 41 is formed to protrude downward from the via portion 42 below the bottom surface of the device layer 10. The lower bump 41 may be formed to have a convex curvature downward.

The wiring pattern 43 may cover a portion of the top surface of the device layer 10 and may form at least part of circuit wiring on the top surface of the interposer 1.

The upper bump 42a extends upward from the via portion 42 and may protrude above the wiring pattern 43. That is, the upper bump 42a may be formed to have a greater thickness than the wiring pattern 43.

The second conductive metal layer 60 is formed of a second conductive metal and may be formed on the top surface of the upper bump 42a.

The first and second conductive metals are electrically conductive and may be the same material or different materials.

The first and second conductive metals may be selected from materials capable of low-temperature bonding by eutectic fusion, diffusion, or similar processes. The first and second conductive metals may be bonded by eutectic fusion, diffusion, or similar processes at a temperature lower than the melting points of each conductive metal while in contact and/or under pressure. For example, the first conductive metal may include copper, and the second conductive metal may include tin. Alternatively, the first and second conductive metals may be the same conductive metal.

Due to the structure and characteristics of the interposer 1 described above, low-temperature bonding is possible when stacking interposers 1. Specifically, the second conductive metal layer 60 of a lower interposer 1 comes into contact with the lower bump 41 of an upper interposer 1. In a relatively low-temperature environment (lower than the melting points of the first and second conductive metals), pressure is applied, and bonding occurs through eutectic fusion, diffusion, or similar processes.

This significantly reduces the time required for the interposer stacking process and, because the integration occurs under relatively low-temperature conditions, minimizes adverse effects caused by heat.

Hereinafter, a method of manufacturing the interposer 1 according to an embodiment of the present invention will be described.

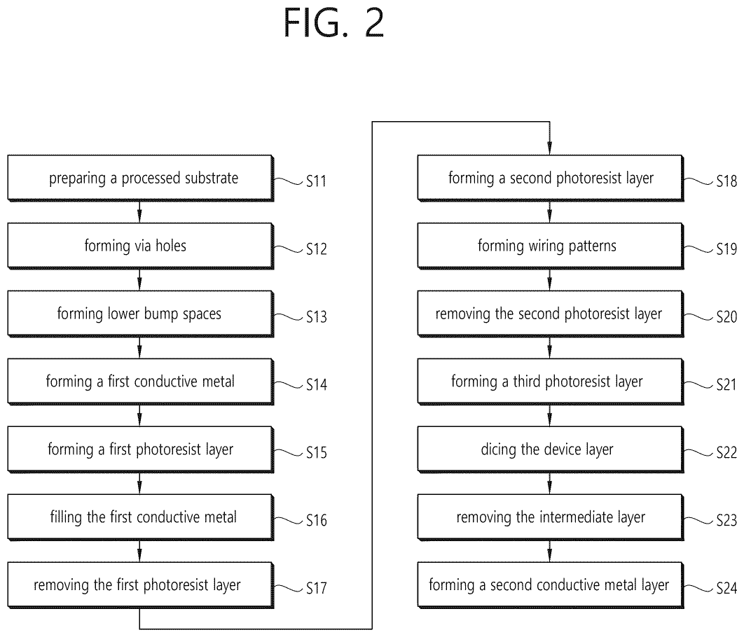

FIG. 2 is a flowchart illustrating an interposer manufacturing method according to an embodiment of the present invention, and FIGS. 3A and 3B are views for explaining the interposer manufacturing method according to an embodiment of the present invention.

Referring to FIG. 2, the interposer manufacturing method according to an embodiment of the present invention may include: preparing a processed substrate (S11), forming via holes (S12), forming lower bump spaces (S13), forming a first conductive metal layer (S14), forming a first photoresist layer (S15), filling the first conductive metal (S16), removing the first photoresist layer (S17), forming a second photoresist layer (S18), forming wiring patterns (S19), removing the second photoresist layer (S20), forming a third photoresist layer (S21), dicing the device layer (S22), removing the intermediate layer (S23), and forming a second conductive metal layer (S24).

In the step of preparing the processed substrate (S11), a processed substrate including the device layer 10 of the interposer 1 is prepared.

Referring to FIG. 3A, the processed substrate may include a handling layer 30, an intermediate layer 20, and a device layer 10. The intermediate layer 20 is laminated on the handling layer 30, and the device layer 10 is laminated on the intermediate layer 20. The handling layer 30 and the device layer 10 may be silicon layers, and the intermediate layer 20 may be a silicon oxide (SiO₂) layer. The intermediate layer 20 may have a thickness of approximately 1 μm.

Referring to FIG. 3A, in the step of forming via holes (S12), at least one via hole 11 vertically penetrating the device layer 10 may be formed. The via hole 11 may be formed using deep reactive ion etching (DRIE) or a laser. However, the process for forming the via hole 11 is not limited thereto and may be performed by other methods.

Referring to FIG. 3A, in the step of forming lower bump spaces (S13), a portion of the intermediate layer 20 is removed to form a lower bump space 21 beneath the via hole 11. When the handling layer 30 and the device layer 10 are silicon layers and the intermediate layer 20 is a silicon oxide layer, the exposed intermediate layer 20 through the via hole 11 may be etched using a process that preferentially etches the silicon oxide layer to form the lower bump space 21.

Referring to FIG. 3A, in the step of forming the first conductive metal layer (S14), a first conductive metal layer 40 including the lower bump 41 is formed. The first conductive metal layer 40 is formed of the first conductive metal. The first conductive metal may include at least one of copper and tin.

The lower bump 41 may be formed by filling the lower bump space 21 with the first conductive metal. For example, the lower bump 41 may be formed by depositing a seed layer of the first conductive metal in the lower bump space 21 using a sputtering process, followed by forming the lower bump 41 from the first conductive metal. However, the process for forming the lower bump 41 is not limited thereto and may be performed by other methods.

When the intermediate layer 20 is formed with a thickness of approximately 1 μm, the lower bump 41 may also be formed with a thickness of approximately 1 μm.

The first conductive metal layer 40 is formed on the inner walls of the via hole 11 and on the top surface of the device layer 10. The first conductive metal layer 40 may be formed such that the layer on the top surface of the device layer 10 and the lower bump 41 are connected through the layer formed on the inner walls of the via hole 11. The first conductive metal layer 40 may be formed by an electroplating process. However, the process for forming the first conductive metal layer 40 is not limited thereto and may be performed by other methods.

Referring to FIG. 3A, in the step of forming the first photoresist layer (S15), a first photoresist layer 51 is formed on the top surface of the first conductive metal layer 40. The first photoresist layer 51 may include through-holes corresponding to the via holes 11.

Referring to FIG. 3A, in the step of filling the first conductive metal (S16), a via portion 42 filled with the first conductive metal may be formed inside the via hole 11. For example, the upper portion of the first photoresist layer 51 and the via hole 11 may be plated with the first conductive metal to form the via portion 42 filled with the first conductive metal. During the plating process, a plating layer of the first conductive metal may also be formed on the top of the first photoresist layer 51.

By controlling the thickness of the plating layer in the plating process of the first conductive metal, an upper bump 42a may be formed on the top of the via portion 42. The upper bump 42a may be formed to protrude above the first conductive metal layer 40 laminated on the top surface of the device layer 10 in the step of forming the first conductive metal layer (S14).

In the step of removing the first photoresist layer (S17), the first photoresist layer 51 with the plating layer of the first conductive metal formed on the top surface is removed.

Referring to FIG. 3B, in the step of forming the second photoresist layer (S18), a second photoresist layer 52 is formed on the top surface of the first conductive metal layer 40 exposed on the top. The second photoresist layer 52 may include patterns corresponding to the wiring patterns 43.

Referring to FIG. 3B, in the step of forming wiring patterns (S19), portions of the first conductive metal layer 40 not protected by the second photoresist layer 52 are etched to form wiring patterns 43 on the top surface of the device layer 10.

In the step of removing the second photoresist layer (S20), the second photoresist layer 52 is removed.

Referring to FIG. 3B, in the step of forming a third photoresist layer (S21), a third photoresist layer 53 is formed on the wiring patterns 43 and the top surface of the device layer 10. The third photoresist layer 53 may include through-holes corresponding to patterns for dicing the device layer 10 and patterns for forming the second conductive metal layer 60. The patterns for dicing the device layer 10 are positioned on the top surface of the device layer 10, and the patterns for forming the second conductive metal layer 60 may be positioned on the upper bump 42a.

Referring to FIG. 3B, in the step of dicing the device layer (S22), the device layer 10 is selectively etched so that the device layer 10 may be diced into a plurality of separate device layers. When the device layer 10 is a silicon layer, a selective etching process for silicon may be performed.

Referring to FIG. 3B, in the step of removing the intermediate layer (S23), the intermediate layer 20 is etched to separate the handling layer 30 from the device layer 10. When the intermediate layer 20 is a silicon oxide layer, a selective etching process for silicon oxide may be performed.

Since the lower bump 41 exists between the device layer 10 and the handling layer 30, even after removing the intermediate layer 20, the device layer 10 and the handling layer 30 may remain separated from each other.

Referring to FIG. 3B, in the step of forming the second conductive metal layer (S24), the second conductive metal layer 60 is formed on the top surface of the upper bump 42a. The second conductive metal layer 60 is formed of the second conductive metal, which may include at least one of copper and tin.

The second conductive metal layer 60 may be formed by depositing the second conductive metal on the top surface of the third photoresist layer 53 while the third photoresist layer 53 is present.

Thereafter, the third photoresist layer 53 is removed, and the interposer 1 is transferred from the handling layer 30, thereby completing the manufacturing of the interposer 1.

Because the interposer manufacturing method according to the above-described embodiment of the present invention is a method for manufacturing an ultra-thin interposer based on an SOI wafer, it does not require conventional carrier wafer thinning or debonding processes, and it is free from thin device damage and warping problems caused by those processes.

Hereinafter, a method for integrating electronic components according to an embodiment of the present invention will be described.

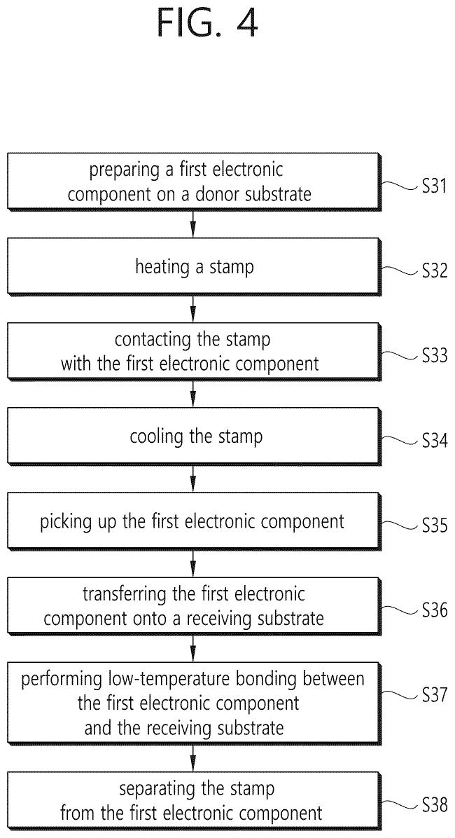

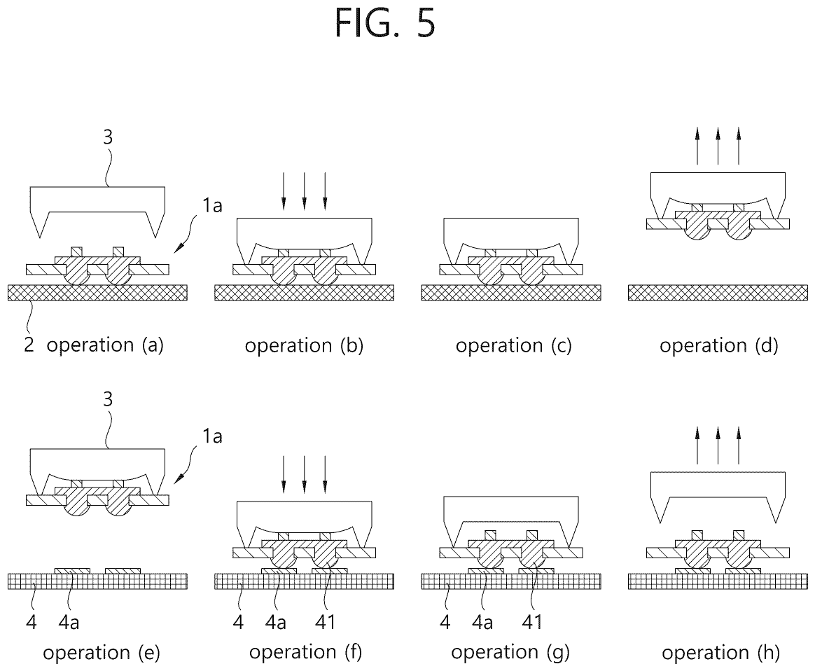

FIG. 4 is a flowchart illustrating an electronic component integration method according to an embodiment of the present invention, and FIG. 5 is a diagram for explaining the electronic component integration method according to an embodiment of the present invention.

Referring to FIG. 4, the electronic component integration method according to an embodiment of the present invention includes preparing a first electronic component on a donor substrate (S31), heating a stamp (S32), contacting the stamp with the first electronic component (S33), cooling the stamp (S34), picking up the first electronic component (S35), transferring the first electronic component onto a receiving substrate (S36), performing low-temperature bonding between the first electronic component and the receiving substrate (S37), and separating the stamp from the first electronic component (S38).

Referring to FIG. 5, in the step of preparing the first electronic component on the donor substrate (S31), the first electronic component 1a is positioned on the donor substrate 2. The first electronic component 1a may be the interposer 1 described above. Alternatively, the first electronic component 1a may be a semiconductor chip (e.g., a transistor, diode, memory cell), a semiconductor packaging element (interposer, heatsink, or other passive elements such as capacitors or resistors), or the like.

The first electronic component 1a, similar to the interposer 1 described above, may be formed such that the first conductive metal is exposed at the lower side and a second conductive metal electrically connected to the first conductive metal is exposed at the upper side. The first electronic component 1a may be formed so that a lower bump formed of the first conductive metal is exposed downward, and the second conductive metal electrically connected to the lower bump is exposed upward.

In the step of heating the stamp (S32), the stamp 3 is heated to a predetermined temperature range. The stamp 3 may be a polymer stamp including a shape memory polymer (SMP). The SMP stamp 3 is heated to a temperature above its glass transition temperature.

Referring to FIG. 5, in the step of contacting the stamp with the first electronic component (S33), the heated stamp 3 is brought into contact with the top surface of the first electronic component 1a, increasing the contact area between the stamp 3 and the first electronic component 1a. The SMP stamp 3, heated above the glass transition temperature and contacting the top surface of the first electronic component 1a, deforms according to the shape of the top surface of the first electronic component 1a, thereby increasing the contact area.

In the step of cooling the stamp (S34), the stamp 3 is cooled while remaining in contact with the first electronic component 1a, maintaining the contact area with the first electronic component 1a. In particular, as the SMP stamp 3 cools, its shape may be maintained in contact with the first electronic component 1a.

Referring to FIG. 5, in the step of picking up the first electronic component (S35), the stamp 3 picks up the first electronic component 1a from the donor substrate 2. The first electronic component 1a is separated from the donor substrate 2 while remaining in contact with the stamp 3.

Referring to FIG. 5, in the step of transferring the first electronic component onto the receiving substrate (S36), the first electronic component 1a is positioned on the receiving substrate 4 while remaining in contact with the stamp 3. The receiving substrate 4 may include a metal wiring 4a, at least a portion of which is exposed on the surface. The metal wiring may be formed of the second conductive metal.

Referring to FIG. 5, in the step of performing low-temperature bonding between the first electronic component and the receiving substrate (S37), the stamp 3 presses the first electronic component 1a onto the receiving substrate 4. More specifically, the first conductive metal exposed at the lower side of the first electronic component 1a is brought into contact with the metal wiring 4a of the receiving substrate 4. When the first electronic component 1a is the interposer 1 described above, the lower bump 41 of the interposer 1 contacts the metal wiring 4a of the receiving substrate 4. The first conductive metal of the first electronic component 1a and the metal wiring 4a may be pressed toward each other.

The first conductive metal of the first electronic component 1a and the metal wiring 4a are heated to a temperature lower than their respective melting points. The receiving substrate 4 or the process environment may be heated so that the first conductive metal of the first electronic component 1a and the metal wiring 4a are appropriately heated.

The pressure and temperature applied between the first conductive metal of the first electronic component 1a and the metal wiring 4a may be set within a range in which low-temperature bonding by eutectic formation, diffusion, or the like occurs. For example, the first conductive metal may be copper, and the second conductive metal may be tin, or vice versa. Alternatively, the first and second conductive metals may be of the same conductive metal, such as copper or tin. The low-temperature bonding process may be carried out at a temperature below 200° C., and more specifically, within a low-temperature range of about 150° C. to 200° C.

Referring to FIG. 5, in the step of separating the stamp from the first electronic component (S38), the stamp 3 is reheated to a state in which it can be easily separated from the first electronic component 1a, and then the stamp 3 is detached from the first electronic component 1a. The SMP stamp 3 may be heated to a temperature above its glass transition temperature. The heating of the stamp 3 may be performed simultaneously with step S37.

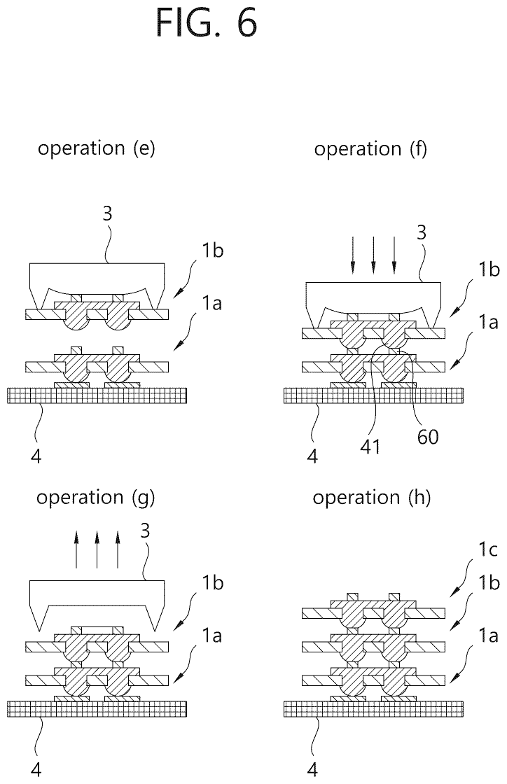

FIG. 6 is a diagram for explaining a method of stacking electronic components using the electronic component integration method according to an embodiment of the present invention.

Referring to FIG. 6, the electronic component integration method according to an embodiment of the present invention may further include picking up a second electronic component 1b and positioning it on the first electronic component 1a, performing low-temperature bonding between the second electronic component 1b and the first electronic component 1a, separating the stamp 3 from the second electronic component 1b, and stacking a third electronic component 1c.

The second electronic component 1b and the third electronic component 1c may be the interposer 1 described above. Alternatively, the second electronic component 1b and the third electronic component 1c may be a semiconductor chip (e.g., a transistor, diode, memory cell), a semiconductor packaging element (interposer, heatsink, or other passive elements such as capacitors or resistors), or the like.

The second electronic component 1b and the third electronic component 1c, similar to the interposer 1 described above, may be formed such that the first conductive metal is exposed at the lower side and a second conductive metal electrically connected to the first conductive metal is exposed at the upper side. The second electronic component 1b and the third electronic component 1c may be formed so that the lower bump formed of the first conductive metal is exposed downward, and the second conductive metal electrically connected to the lower bump is exposed upward.

The step of picking up the second electronic component 1b and positioning it on the first electronic component 1a may be performed similarly to steps S31 to S36 described above. The stamp 3 may pick up the second electronic component 1b from the donor substrate 2. The stamp 3 may position the picked-up second electronic component 1b on the first electronic component 1a already integrated on the receiving substrate 4. The stamp 3 may be an SMP stamp.

The step of performing low-temperature bonding between the second electronic component 1b and the first electronic component 1a may be carried out similarly to step S37 described above. The stamp 3 presses the second electronic component 1b onto the first electronic component 1a. More specifically, the first conductive metal exposed at the lower side of the second electronic component 1b is brought into contact with the second conductive metal exposed at the upper side of the first electronic component 1a. When the first and second electronic components 1a, 1b are the interposer 1 described above, the lower bump 41 of the second electronic component 1b contacts the second conductive metal layer 60 of the first electronic component 1a. The second conductive metal layer 60 of the first electronic component 1a and the lower bump 41 of the second electronic component 1b may be pressed toward each other.

In addition, the second conductive metal exposed at the upper side of the first electronic component 1a and the first conductive metal exposed at the lower side of the second electronic component 1b are heated to temperatures lower than their respective melting points. The receiving substrate 4 or the process environment may be heated so that the second conductive metal of the first electronic component 1a and the first conductive metal of the second electronic component 1b are appropriately heated.

The pressure and temperature applied between the second conductive metal of the first electronic component 1a and the first conductive metal of the second electronic component 1b may be set within a range in which low-temperature bonding by eutectic formation, diffusion, or the like occurs. For example, the first conductive metal may be copper and the second conductive metal may be tin, or vice versa. Alternatively, the first and second conductive metals may be of the same metal, such as copper or tin. The low-temperature bonding process may be carried out at a temperature below 200° C., and more specifically, within a low-temperature range of about 150° C. to 200° C.

The step of separating the stamp 3 from the second electronic component 1b may be carried out similarly to step S38 described above. After the low-temperature bonding of the first and second electronic components 1a, 1b is completed, the stamp 3 is heated to a state in which it can be easily separated from the second electronic component 1b, and then detached from the second electronic component 1b. The SMP stamp 3 may be heated to a temperature above its glass transition temperature. The heating of the stamp 3 may be performed simultaneously with the step of low-temperature bonding between the first and second electronic components 1a, 1b.

The step of stacking the third electronic component 1c may be performed in a manner similar to the steps performed for stacking the second electronic component 1b on the first electronic component 1a. The third electronic component 1c is picked up and positioned on the second electronic component 1b, bonded at a low temperature to the second electronic component 1b, and then the stamp 3 is separated from the third electronic component 1c.

Further, a plurality of additional electronic components may be sequentially stacked on top of the third electronic component 1c.

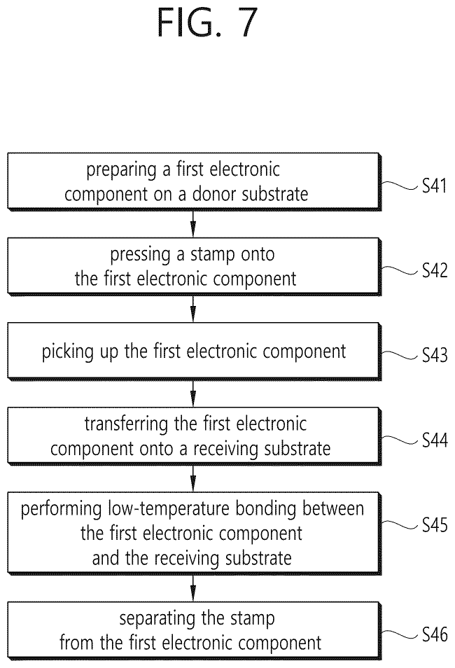

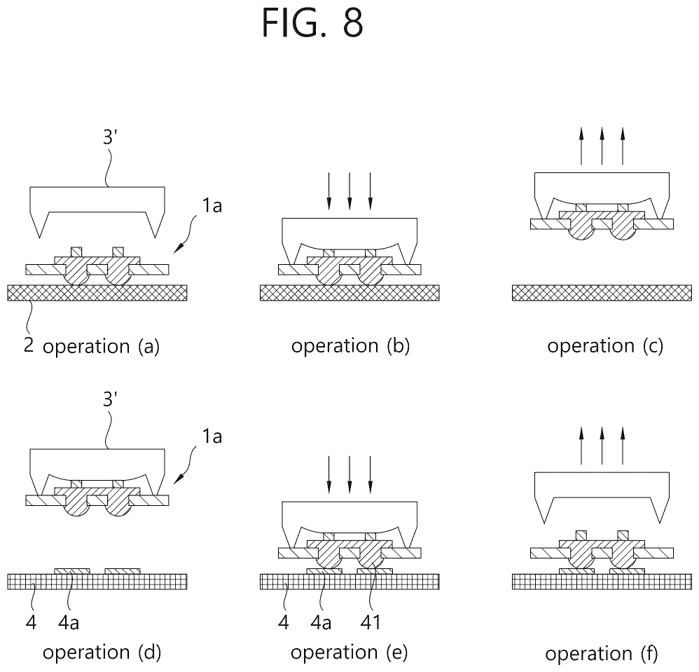

FIG. 7 is a flowchart illustrating an electronic component integration method according to another embodiment of the present invention, and FIG. 8 is a diagram for explaining the electronic component integration method according to another embodiment of the present invention.

Referring to FIG. 7, the electronic component integration method according to another embodiment of the present invention may include preparing a first electronic component on a donor substrate (S41), pressing a stamp onto the first electronic component (S42), picking up the first electronic component (S43), transferring the first electronic component onto a receiving substrate (S44), performing low-temperature bonding between the first electronic component and the receiving substrate (S45), and separating the stamp from the first electronic component (S46).

Referring to FIG. 8, in the step of preparing the first electronic component on the donor substrate (S41), the first electronic component 1a is positioned on the donor substrate 2. Further description of the first electronic component 1a has been provided above, and thus additional explanation is omitted.

In the electronic component integration method described with reference to FIGS. 4 to 6, the stamp 3 had to be heated and cooled to pick up the first electronic component 1a. However, the stamp 3′ used in the electronic component integration method according to this embodiment is a polymer stamp including PDMS (polydimethylsiloxane), and the first electronic component 1a can be picked up using the inherent adhesive force of the stamp 3′. Therefore, in the electronic component integration method according to this embodiment, the steps of heating and cooling the stamp 3′ may be omitted.

Referring to FIG. 8, in the step of pressing the stamp onto the first electronic component (S42), the stamp 3′ is pressed onto the upper surface of the first electronic component 1a to bring the stamp 3′ into contact with the first electronic component 1a. The PDMS stamp 3′ increases the contact area with the first electronic component 1a, and the first electronic component 1a adheres to the PDMS stamp 3′ due to the adhesive force acting over the contact area. PDMS is a representative elastomer with high chemical resistance, minimizing damage to the first electronic component 1a during contact.

Referring to FIG. 8, in the step of picking up the first electronic component (S43), the stamp 3′ picks up the first electronic component 1a from the donor substrate 2. The first electronic component 1a is separated from the donor substrate 2 while adhered to the stamp 3′.

Referring to FIG. 8, in the step of transferring the first electronic component onto the receiving substrate (S44), the first electronic component 1a is positioned on the receiving substrate 4 while adhered to the stamp 3′. The receiving substrate 4 may include metal wiring 4a at least partially exposed on its surface. The metal wiring 4a may be formed of the second conductive metal.

Referring to FIG. 8, in the step of low-temperature bonding of the first electronic component to the receiving substrate (S45), the stamp 3′ presses the first electronic component 1a onto the receiving substrate 4. The first conductive metal of the first electronic component 1a and the metal wiring 4a of the receiving substrate 4 undergo low-temperature bonding by eutectic formation, diffusion, or the like. Details of this step are described above with reference to step S37 of the previously described embodiment, and further explanation is omitted.

Referring to FIG. 8, in the step of separating the stamp from the first electronic component (S46), the stamp 3′ is lifted and separated from the first electronic component 1a. Since low-temperature bonding has been achieved between the first electronic component 1a and the receiving substrate 4, the first electronic component 1a remains on the receiving substrate 4 even as the stamp 3′ is lifted.

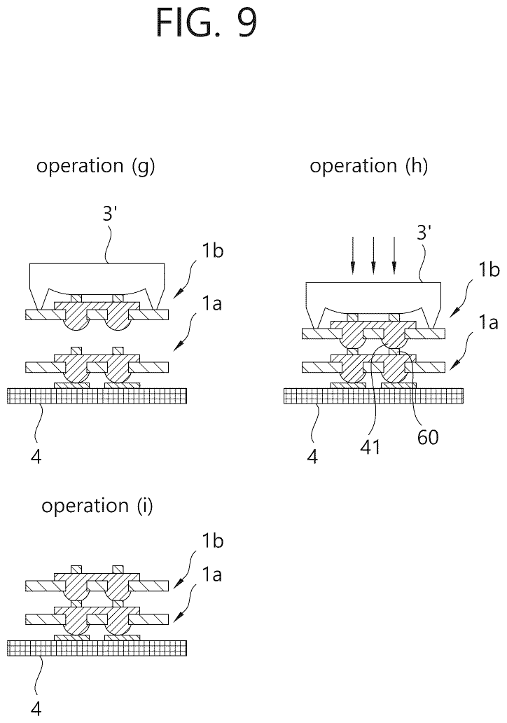

FIG. 9 is a diagram for explaining a method of stacking electronic components using the electronic component integration method according to another embodiment of the present invention.

Referring to FIG. 9, the electronic component integration method according to another embodiment may further include picking up a second electronic component 1b and placing it on the first electronic component 1a, low-temperature bonding of the second electronic component 1b to the first electronic component 1a, and separating the stamp 3′ from the second electronic component 1b.

The second electronic component 1b may be the interposer 1 described above. Alternatively, the second electronic component 1b may be a semiconductor chip (e.g., a transistor, diode, memory cell, etc.) or a semiconductor packaging element (interposer, heat sink, or other passive element such as a capacitor or resistor).

The second electronic component 1b may be formed similarly to the interposer 1 described above, with the first conductive metal exposed at the lower side and the second conductive metal, electrically connected to the first conductive metal, exposed at the upper side. The second electronic component 1b may be formed such that a lower bump formed of the first conductive metal is exposed at the lower side, and the second conductive metal electrically connected to the lower bump is exposed at the upper side.

The step of picking up the second electronic component 1b and placing it on the first electronic component 1a may be performed similarly to steps S41 to S44 described above. The stamp 3′ may pick up the second electronic component 1b from the donor substrate 2. The stamp 3′ may position the picked-up second electronic component 1b on the first electronic component 1a already integrated on the receiving substrate 4. The stamp 3′ may be a PDMS stamp.

The step of low-temperature bonding of the second electronic component 1b to the first electronic component 1a may be performed similarly to steps S37 and S45 described above. The stamp 3′ presses the second electronic component 1b onto the first electronic component 1a. More specifically, the first conductive metal exposed at the lower side of the second electronic component 1b comes into contact with the second conductive metal exposed at the upper side of the first electronic component 1a. If the first and second electronic components 1a, 1b are the interposer 1 described above, the lower bump 41 of the second electronic component 1b comes into contact with the second conductive metal layer 60 of the first electronic component 1a. The second conductive metal layer 60 of the first electronic component 1a and the lower bump 41 of the second electronic component 1b may be pressed toward each other.

In addition, the second conductive metal exposed at the upper side of the first electronic component 1a and the first conductive metal exposed at the lower side of the second electronic component 1b are heated to a temperature lower than their respective melting points. The receiving substrate 4 or the process chamber may be heated such that the second conductive metal of the first electronic component 1a and the first conductive metal of the second electronic component 1b are heated.

The pressure and temperature between the second conductive metal of the first electronic component 1a and the first conductive metal of the second electronic component 1b may be determined within a range in which low-temperature bonding by eutectic formation, diffusion, or the like occurs between the two metals. The first conductive metal may be copper, and the second conductive metal may be tin. Alternatively, the first conductive metal may be tin, and the second conductive metal may be copper. Alternatively, the first and second conductive metals may be of the same metal, such as copper or tin. The low-temperature bonding process may be performed at a temperature below 200° C., and more specifically, in a low-temperature environment of about 150° C. to 200° C.

The step of separating the stamp 3′ from the second electronic component 1b may be performed similarly to step S46 described above. Once low-temperature bonding between the first electronic component 1a and the second electronic component 1b is completed, the stamp 3′ is lifted and separated from the second electronic component 1b.

Similarly to the steps performed to stack the second electronic component 1b on the first electronic component 1a, a third electronic component may be picked up and positioned on the second electronic component 1b, followed by low-temperature bonding of the third electronic component to the second electronic component 1b, and separation of the stamp 3′ from the third electronic component, thereby stacking the third electronic component on the second electronic component 1b.

In addition, multiple electronic components may be sequentially stacked and integrated on top of the third electronic component.

The electronic component integration methods according to the above embodiments may use a dry-adhesion type polymer stamp (SMP or PDMS) to transfer the electronic components, enabling 2.5D or 3D integration. By using a dry-adhesion method, energy and resources required for the process can be reduced.

Integration of ultrathin devices requires high precision and sensitivity, and conventional high-temperature/high-pressure integration processes may cause damage to ultrathin devices or degrade the quality/performance of the product. In contrast, the electronic component integration methods according to the above embodiments allow bonding in a low-temperature/low-pressure environment, thereby minimizing such issues. Moreover, by using a dry-adhesion type polymer stamp (SMP or PDMS) to transfer and align the electronic components, and performing bonding in a low-temperature/low-pressure environment, high-speed and high-precision integration processes are achievable.

Transferring and aligning electronic components from the donor substrate to the receiving substrate may take less than two minutes, and heating to the temperature required for low-temperature bonding may take less than one minute, allowing high-speed integration within three minutes.

Furthermore, bonding between the substrate and the electronic components, or between the electronic components themselves, is achieved by direct metal-to-metal connection without using separate conductive adhesives, thereby providing higher process efficiency and enabling high-precision bonding.

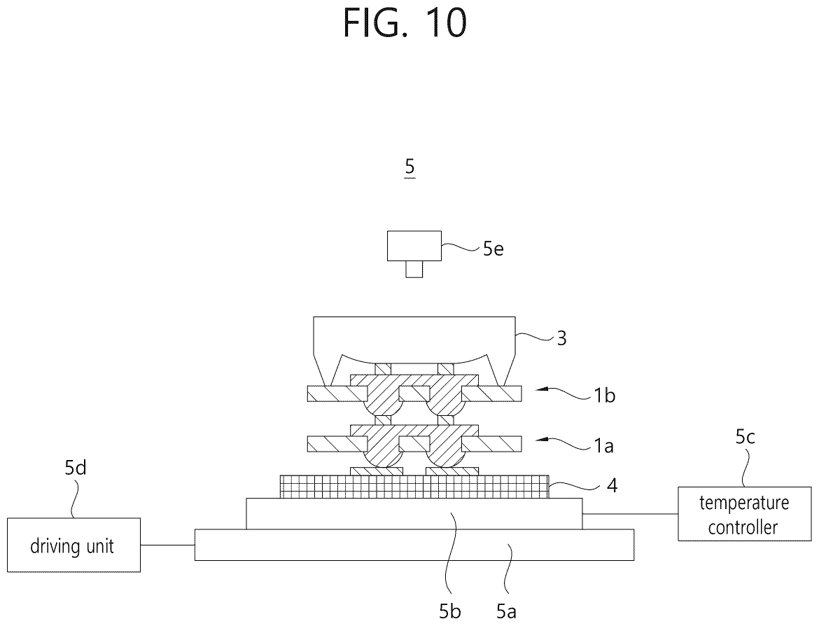

FIG. 10 is a schematic diagram illustrating an electronic component integration apparatus according to an embodiment of the present invention.

Referring to FIG. 10, an electronic component integration apparatus 5 according to an embodiment of the present invention may perform the electronic component integration methods according to the above-described embodiments, and may include a stage 5a, a heater 5b, a temperature controller 5c, a driving unit 5d, and a microscope 5e.

The heater 5b is located on the stage 5a, and the receiving substrate 4 may be placed on an upper surface of the heater 5b. The stage 5a may move the heater 5b in a planar direction via the driving unit 5d. The heater 5b may be heated or cooled to a set temperature by the temperature controller 5c.

The microscope 5e provides a magnified image so that the first electronic component 1a picked up by the stamp 3 is aligned at an exact position on the receiving substrate 4, and the second electronic component 1b is aligned at an exact position on the first electronic component 1a. Based on the magnified image obtained by the microscope 5e, the stamp 3 may position the picked-up first electronic component 1a or second electronic component 1b.

Although not shown, the electronic component integration apparatus 5 may further include a stamp transfer unit configured to move the stamp 3 such that the stamp 3 can pick up electronic components 1a, 1b from the donor substrate 2 and transfer them onto the receiving substrate 4.

Although embodiments of the present disclosure have been described with reference to the accompanying drawings, a person with ordinary knowledge in the technical field to which the present disclosure belongs will be able to understand that the present disclosure may be implemented in other specific forms without changing the technical spirit or essential features. Therefore, the embodiments described above should be understood as illustrative in all respects and not limiting. The scope of the present disclosure is indicated by claims to be described later rather than the detailed description above, and all changes or modified forms derived from the meaning and scope of the claims and their equivalent concepts should be construed as being included in the scope of the present disclosure.

What is claimed is:

1. A method for integrating electronic components using a polymer stamp, comprising:
picking up a first electronic component with a first conductive metal exposed at a lower portion thereof using a polymer stamp;
positioning the first electronic component on a substrate having a metal wiring at least partially exposed on a surface using the polymer stamp;
pressing and heating the first conductive metal and the metal wiring using the polymer stamp so that low-temperature bonding occurs between the first conductive metal and the metal wiring; and
separating the first electronic component from the polymer stamp.

2. The method of claim 1, wherein a heating temperature in the pressing and heating step is lower than a melting point of the first conductive metal and the metal wiring.

3. The method of claim 1, wherein the first electronic component further comprises a second conductive metal electrically connected to the first conductive metal and exposed at an upper portion thereof, the method further comprising:
picking up a second electronic component with a first conductive metal exposed at a lower portion thereof using the polymer stamp;
positioning the second electronic component on the first electronic component using the polymer stamp;
pressing and heating the second conductive metal of the first electronic component and the first conductive metal of the second electronic component using the polymer stamp so that low-temperature bonding occurs; and
separating the second electronic component from the polymer stamp.

4. The method of claim 3, wherein a heating temperature in the pressing and heating step is lower than a melting point of the second conductive metal of the first electronic component and the first conductive metal of the second electronic component.

5. The method of claim 1, wherein the polymer stamp comprises a shape memory polymer (SMP).

6. The method of claim 5, further comprising, prior to picking up the first electronic component using the polymer stamp:
heating the polymer stamp to a temperature above a glass transition temperature;
pressing the heated polymer stamp onto the first electronic component to increase a contact area between the polymer stamp and the first electronic component; and
cooling the polymer stamp.

7. The method of claim 5, wherein a heating temperature in the pressing and heating step is equal to or higher than the glass transition temperature.

8. The method of claim 1, wherein the polymer stamp comprises polydimethylsiloxane (PDMS).

9. The method of claim 1, wherein the first conductive metal comprises copper.

10. The method of claim 3, wherein the second conductive metal comprises tin.

11. The method of claim 1, wherein the first electronic component comprises an interposer including:
a device layer penetrated by the first conductive metal,
a lower bump formed by the first conductive metal exposed at a lower portion of the device layer,
an upper bump formed by the first conductive metal exposed at an upper portion of the device layer, and
a second conductive metal formed on an upper surface of the upper bump.

12. The method of claim 3, wherein the second electronic component comprises an interposer including:
a device layer penetrated by the first conductive metal,
a lower bump formed by the first conductive metal exposed at a lower portion of the device layer,
an upper bump formed by the first conductive metal exposed at an upper portion of the device layer, and
a second conductive metal formed on an upper surface of the upper bump.
